(19) United States
(12) Patent Application Publication
(10) Pub. No.: US 2009/0051676 A1
(43) Pub. Date: Feb. 26, 2009

(54) DRIVING APPARATUS FOR DISPLAY

(76) Inventors: Gyu Hyeong Cho, Daejeon (KR); Hyung-Min Lee, Daegu (KR); Young-Suk Son, Daejeon (KR); Yong-Joon Jeon, Daejeon (KR); Jin Yong Jeon, Daegu (KR); Seung-Chui Jung, Gwangju (KR)

Correspondence Address: BUCHANAN, INGERSOLL & ROONEY PC, POST OFFICE BOX 1404, ALEXANDRIA, VA, 22313-1404, US

(21) Appl. No.: 11/930,888

(22) Filed: Oct. 31, 2007

(30) Foreign Application Priority Data
Aug. 21, 2007 (KR) 10-2007-0083741
Aug. 21, 2007 (KR) 10-2007-0083743

(51) Int. Cl. G09G 5/00; H03M 1/66

(52) U.S. Cl. 345/211; 341/144

(57) ABSTRACT

A driving apparatus for a display is provided. The driving apparatus for a display comprises: a digital/analog converter for receiving an input voltage lower than a source voltage used in a buffer amplifier for output driving, generating a plurality of reference voltages, and selecting a reference voltage corresponding to an M (M is a positive integer) bit data signal; and an amplifier for amplifying the reference voltage selected by the digital/analog converter. Therefore, a circuit area and power consumption of the driving apparatus for a display can be minimized.

### RELATED APPLICATIONS

This Nonprovisional application claims priority under 35 U.S.C. §119(a) on Korean Patent Application No. 10-2007-0083741 and 10-2007-0083743 filed on Aug. 21, 2007 the entire contents of which are hereby incorporated by reference.

### BACKGROUND OF THE INVENTION

1. Field of the Invention

The present invention relates to a driving apparatus for a display and more particularly, to a driving apparatus for a flat panel display.

2. Description of the Related Art

In general, a Flat Panel Display (FPD) apparatus indicates a flat digital image display apparatus having a thickness of several centimeters to millimeters. The flat panel display apparatus can be roughly divided into an Active-Matrix Liquid Crystal Display (AMLCD) and an Active-Matrix Organic Light Emitting Diode (AMOLED).

FIG. 1 is a block diagram illustrating a configuration of a general display apparatus. A pixel circuit 105 of a display panel is driven by a display driver integrated circuit. The display driver integrated circuit comprises a column driver integrated circuit (Column Driver IC) 102 and a row driver integrated circuit 103. In the display driver integrated circuit, the row driver integrated circuit 103 sequentially selects rows of a pixel circuit 105 and then the column driver integrated circuit 102 supplies a voltage or a current corresponding to a gray scale to be expressed in each pixel. Accordingly, the display driver integrated circuit is driven. Further, signals of the column driver integrated circuit 102 and the row driver integrated circuit 103 are controlled by a timing controller 101. A power source for driving the display apparatus is supplied from a DC-DC converter 100.

FIG. 2 is a block diagram illustrating a configuration of the column driver integrated circuit 102 shown in FIG. 1. The column driver integrated circuit 102 comprises a shift register 200, a first latch unit 201, a second latch unit 202, a digital/analog converter 203, and an output unit 204. Further, the column driver integrated circuit 102 can comprises a reference voltage source 206 for generating a reference voltage and supplying the generated reference voltage to the column driver integrated circuit 102.

The output quantity(2^{N}) of a reference voltage output to each channel from the first latch unit 201 is determined by the quantity (N) of a digital bit of input RGB (Red, Green, Blue) signals. In the case of a dot inversion method is applied, a digital/analog converter in an odd-numbered line among pixel circuits selects one of 2^{N} positive gamma reference voltages, and a digital/analog converter in an even-numbered line adjacent to the odd-numbered line selects one of 2^{N} negative gamma reference voltages.

The reference voltage source 206 generates a plurality of reference voltages by using a resistor string. Each the resistor string exists in every column driver integrated circuit 102. Each digital/analog converter 203 exists in every channel. Therefore, several hundreds of the digital/analog converters 203 exist in every column driver integrated circuit 102 and thus the number of the digital/analog converter is an important factor for determining an area of a driving apparatus for a display.

FIGS. 3 and 4 are diagrams illustrating a driving apparatus for a display in the related art.

The driving apparatus for a display shown in FIG. 3 comprises a level shifter 310, a decoder 320, a reference voltage source 300, a digital/analog converter 330, and an output unit 340.

The reference voltage source 300 receives a source voltage used in a buffer amplifier for output driving and generates a number of reference voltages using a resistor string. A reference voltage generated by the resistor string has a value of 0V to 12V (or 18V). The reference voltages are supplied to a plurality of switches provided in the digital/analog converter 330. The plurality of switches select a reference voltage corresponding to a data signal output from the decoder 320. That is, a reference voltage is selected by a switching operation of the plurality of switches according to a data signal output from the decoder 320. The decoder 320 receives a data signal having voltage level of 0V to 3.3V (or 5V) from a latch unit. A digital voltage level processed in the decoder 320 should be amplifier because the plurality of switches provided in the digital/analog converter 330 should control a reference voltage having a range of about 0V to 12V. Accordingly, the level shifter 310 provided in the front of the decoder 320 amplifies a voltage level for processing a data signal in the decoder 320 to a level of a source voltage used in a buffer amplifier for output driving. The decoder 320 and the digital/analog converter 330 should increase a minimum size of a plurality of switches provided within the decoder 320 and the digital/analog converter 330 in order to process a high level of voltage of about 12V to 18V. As a size of the plurality of switches increases, an area of the decoder 320 and the digital/analog converter 330 also increases.

The driving apparatus for a display of FIG. 4 comprises a decoder 410, a level shifter 420, a reference voltage source 400, a digital/analog converter 430, and an output unit 440. The driving method of the driving apparatus for a display of FIG. 4 is identical with that of the driving apparatus for a display described with reference to FIG. 3. However, unlike FIG. 3, the level shifter 420 is provided in a next stage of the decoder 410. The decoder 410 processes a data signal having a voltage level of 0V to 3.3V and outputs the processed data signal to the level shifter 420. The level shifter 420 performs a function of amplifying a data signal of a low voltage level so that a plurality of switches provided the digital/analog converter 430 perform a switching operation. Accordingly, because the plurality of switches provided in the decoder 410 process a data signal of a low voltage level, a size thereof can be reduced. However, because transistors provided in the digital/analog converter 430 control a reference voltage using a data signal amplified to a high voltage level by the level shifter 420, a size of the plurality of switches provided in the digital/analog converter 430 does not decrease. Further, because the level shifter 420 receives a data signal output from the decoder 410, the level shifter 420 should be provided by the quantity of the data signal. For example, In the case of the level shifter 420 receives a data signal output from an 8 bit decoder, the level shifters 420 of 2⁸=256 should be provided. The area of the driving apparatus for a display increases again by the additionally provided level shifter 420. Therefore, increasing of an area occupied by the level shifter 420 and decreasing of a decoder size have a trade-off relationship. Finally, an area of a driving apparatus for a display is increased.

[Document 1] “An 8-bit Digital Data Driver for Color TFT-LCDs” F. Kato, M. Yotsuyanagi, M. Ishida SID 96 DIGEST VOL 27, 1996, pages 247-250

### SUMMARY OF THE INVENTION

An aspect of the present invention is to provide a driving apparatus for a display that can minimize a circuit area and power consumption thereof.

In one general aspect, a driving apparatus for a display comprises: a digital/analog converter for receiving an input voltage lower than a source voltage used in a buffer amplifier for output driving, generating a plurality of reference voltages, and selecting a reference voltage corresponding to an M (M is a positive integer) bit data signal; and an amplifier for amplifying the reference voltage selected by the digital/analog converter.

The digital/analog converter may comprise: a reference voltage source for generating the plurality of reference voltages using a resistor string; a decoder for outputting the M bit data signal; and a selection switch for selecting a reference voltage corresponding to the M bit data signal output from the decoder.

The amplifier may comprise: a first switch in which a reference voltage selected by the digital/analog converter is applied to one end thereof; a second switch whose one end is connected to the other end of the first switch; a first capacitor whose one end is connected to one end of the second switch; a third switch whose one end is connected to the other end of the first capacitor; a second capacitor whose one end is connected to one end of the third switch; a fourth switch whose one end is connected to the other end of the second capacitor and whose the other end is connected to the other end of the third switch; a fifth switch whose one end is connected to one end of the fourth switch; and an output buffer whose inversion terminal is connected to the other end of the first capacitor and whose output terminal is connected to the other end of the fourth switch.

A first voltage, which is a half of the source voltage may be applied to the other end of the fifth switch and a non-inversion terminal of the output buffer.

The first control signal and the second control signal having a phase opposite to each other may be intersectionally applied to the first and second switches, respectively, the first control signal may be applied to the third and fifth switches, and the second control signal may be applied to the fourth switch, so that the first and second capacitors may be charged/discharged.

The amplifier may amplify, the reference voltage by 1/K (K is an integer equal to and greater than 1) times, wherein the reference voltage is selected by the digital/analog converter receiving the input voltage which is 1/k times the source voltage.

The amplifier may amplify the reference voltage by 1/K (K is an integer equal to and greater than 1) times, wherein the reference voltage is selected by the digital/analog converter receiving the input voltage which is 1/K times the source voltage, and subtract the amplified reference voltage from or add the amplified reference voltage to the first voltage.

The driving apparatus may further comprise a first voltage additional circuit comprising a third capacitor whose one end is connected to one end of the second capacitor; a sixth switch whose one end is connected to the other end of the third capacitor; and a seventh switch whose one end is connected to the other end of the third capacitor.

The first control signal and the second control signal may be intersectionally applied to the sixth and seventh switches, respectively and a second voltage corresponding to the N bit data signal among a data signal of an (M+N) bit in which an N (N is a positive integer) bit is added to the M bit is applied to the other end of the sixth switch.

The amplifier may comprise: an eighth switch in which a reference voltage selected by the digital/analog converter is applied to one end thereof; a ninth switch whose one end is connected to the other end of the eighth switch; a fourth capacitor whose one end is connected to one end of the ninth switch; a tenth switch whose one end is connected to the other end of the fourth capacitor; a fifth capacitor whose one end is connected to one end of the tenth switch; an eleventh switch whose one end is connected to the other end of the fifth capacitor and whose the other one is connected to the other end of the tenth switch; a twelfth switch whose one end is connected to one end of the eleventh switch; a comparator whose inversion terminal is connected to the other end of the fourth capacitor and for comparing a magnitude of a voltage detected in an non-inversion terminal and the inversion terminal thereof and outputting a comparison signal; and a current power source for controlling a direction of a current flowing to the fourth and fifth capacitors according to the comparison signal.

The current power source, according to a comparison signal of the comparator, may comprise: a first current power source for outputting a current in a direction of the fourth and fifth capacitors from the current power source; and a second current power source for outputting a current in a direction of the current power source from the fourth and fifth capacitors.

A third voltage, which is a half of the source voltage may be applied to the other end of the twelfth switch and a non-inversion terminal of the comparator.

A third control signal and a fourth control signal having a phase opposite to each other may be intersectionally applied to the eighth and ninth switches, respectively, the third control signal may be applied to the tenth and twelfth switches, and the fourth control signal may be applied to the eleventh switch, so that the fourth and fifth capacitors may be charged/discharged.

The amplifier may amplify the reference voltage by 1/K (K is an integer equal to and greater than 1) times, wherein the reference voltage is selected by the digital/analog converter receiving the input voltage which is 1/k times the source voltage.

The amplifier may amplify the reference voltage by k/2 (K is an integer equal to and greater than 1) times, wherein the reference voltage is selected by the digital/analog converter receiving the input voltage which is 1/K times the source voltage, and subtracts the amplified reference voltage from or adds the amplified reference voltage to the third voltage.

The driving apparatus may further comprise a second voltage additional circuit comprising a sixth capacitor whose one end is connected to one end of the fifth capacitor; a thirteenth switch whose one end is connected to the other end of the sixth capacitor; and a fourteenth switch whose one end is connected to the other end of the sixth capacitor.

The third control signal and the fourth control signal may be intersectionally applied to the thirteenth and fourteenth switches, respectively, and a fourth voltage corresponding to the N bit data signal among a data signal of an (M+N) bit in which an N (N is a positive integer) bit is added to the M bit may be applied to the other end of the thirteenth switch.

Further features will be apparent from the following description, comprising the drawings, and the claims.

### BRIEF DESCRIPTION OF THE DRAWINGS

The details of one or more implementations are set forth in the accompanying drawings and the description below. In the entire description of the present invention, like reference numerals represent corresponding parts throughout various figures.

FIGS. 1 and 2 are block diagrams illustrating a configuration of a general display apparatus in an implementation;

FIGS. 3 and 4 are diagrams illustrating a driving apparatus for a display in the related art;

FIGS. 5 to 7 are diagrams illustrating a driving apparatus for a display in an implementation; and

FIGS. 8 and 9 are diagrams illustrating a driving apparatus for a display in another implementation.

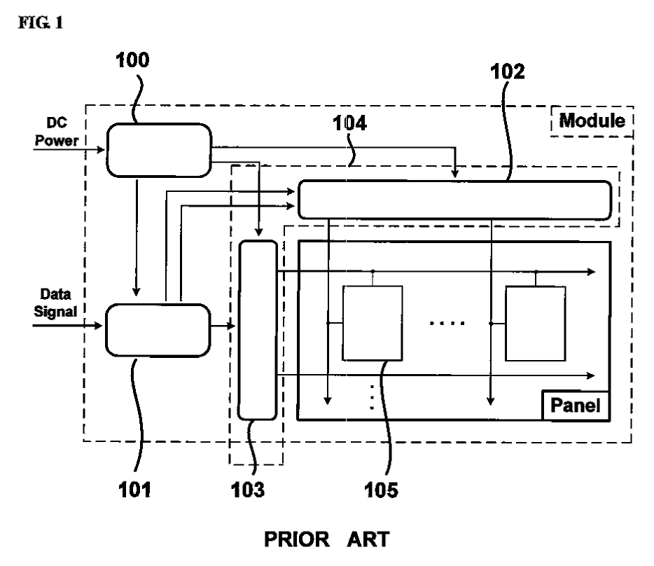

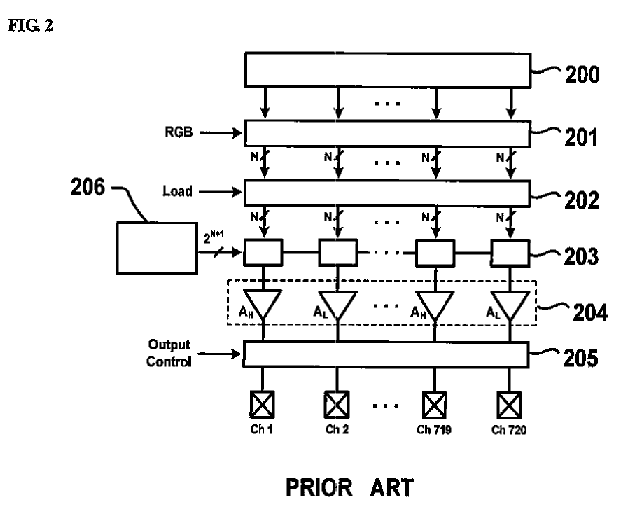

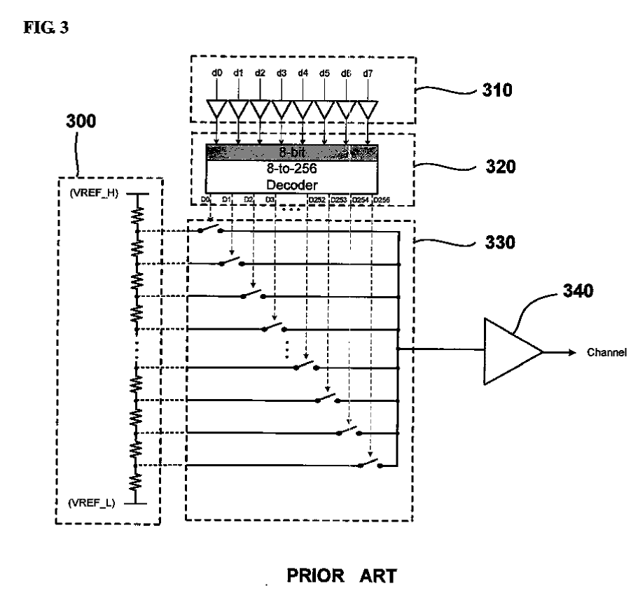

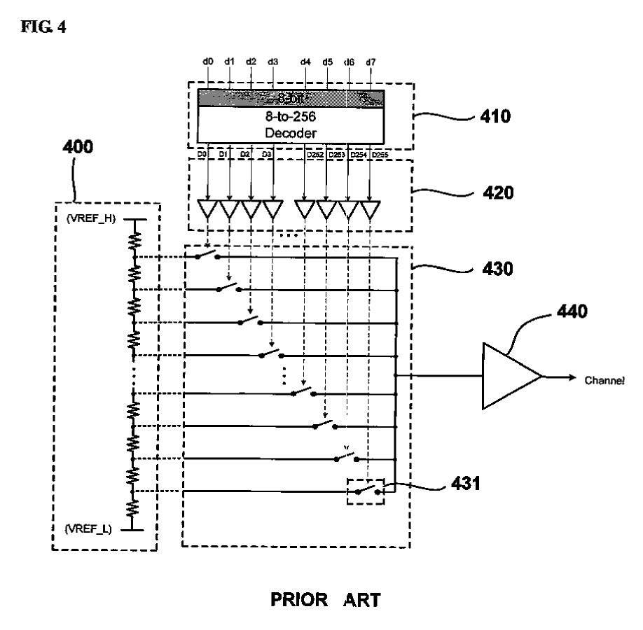

### DETAILED DESCRIPTION OF PREFERRED EMBODIMENTS

Hereinafter, an implementation of the present invention will be described in detail with reference to the attached drawings.

FIGS. 5 to 8 are diagrams illustrating a driving apparatus for a display in an implementation.

Referring to FIG. 5, the driving apparatus for a display in an implementation comprises a digital/analog converter 500 for receiving an input voltage lower than a source voltage used in a buffer amplifier for output driving, generating a reference voltage, and selecting a reference voltage corresponding to an M (M is a positive integer) bit data signal, and an amplifier 540 for amplifying a reference voltage selected by the digital/analog converter 500.

The digital/analog converter 500 comprises a reference voltage source 510 for generating a reference voltage using a resistor string. An input voltage applied to the resistor string has a value lower by 1/K times than a source voltage. For example, an input voltage may have a value reduced from 12V to 18V to about 3V to 4.5V. wherein ‘12V to 18V’ represents a source voltage used in a buffer amplifier for output driving, generally. The reference voltage source 510 received the reduced source voltage generates a plurality of reference voltages using a resistor string. Reference voltages V_{REF}* generated in the reference voltage source 510 are applied to the selection switch unit 530. The selection switch unit 530 comprises a plurality of switches for selecting each of the reference voltages V_{REF}*. The digital/analog converter 500 comprises a decoder 520 for outputting an M bit data signal. The decoder 520 outputs an M bit data signal to each switch provided in the selection switch unit 530. The decoder 520 outputs 2^{M} data signals processed with a digital voltage of 0V to 3.3V (or 5V) to the selection switch unit 530. Accordingly, the selection switch unit 530 selects one reference voltage corresponding to 2^{M} data signals output from the decoder 520. A reference voltage V_{REF}* selected in the selection switch unit 530 is applied to the amplifier 540.

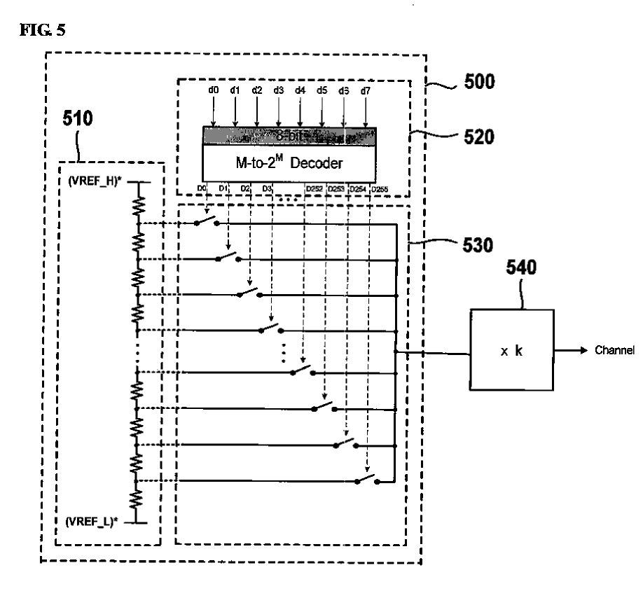

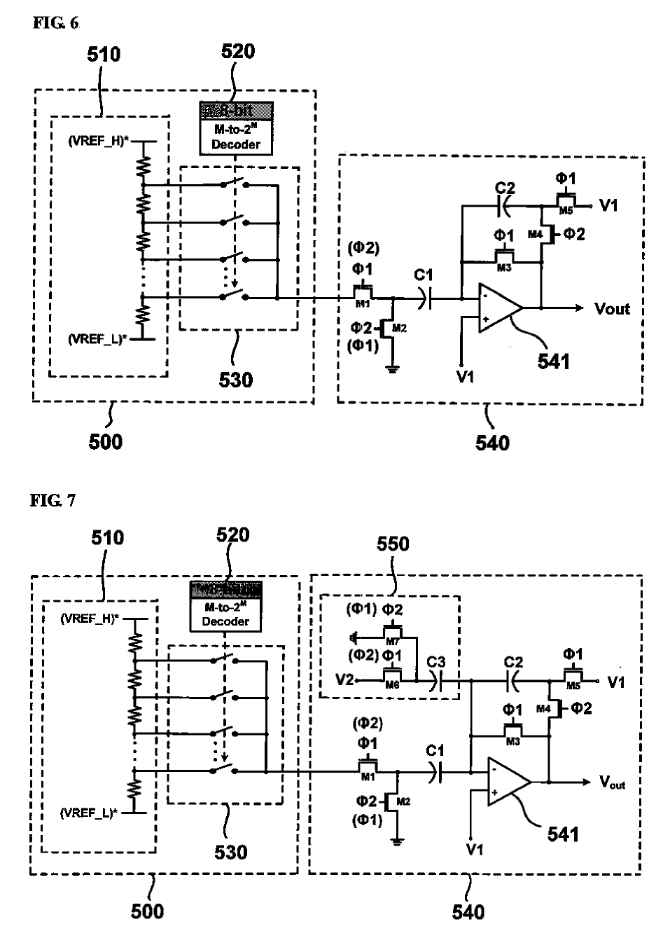

Referring to FIG. 6, the amplifier 540 in an implementation comprises a first switch M1 for receiving a reference voltage V_{REF}* selected in the selection switch 530, a second switch M2 whose one end is connected to the other end of the first switch M1, a first capacitor C1 whose one end is connected to one end of the second switch M2, a third switch M3 whose one end is connected to the other end of the first capacitor C1, a second capacitor C2 whose one end is connected to one end of the third switch M3, a fourth switch M4 whose one end is connected to the other end of the second capacitor C2 and whose the other end is connected to the other end of the third switch M3, a fifth switch M5 whose one end is connected to one end of the fourth switch M4, and an output buffer 541 whose inversion terminal is connected to the other end of the first capacitor C1 and whose output terminal is connected to the other end of the fourth switch M4. A first voltage V1, which is about a half of a source voltage (about 12V to 18V) is applied to the other end of the fifth switch M5 and a non-inversion terminal of the output buffer 541. For example, the first voltage V1 may have a value of 6V to 9V. (when the source voltage may have a value of about 12V to 18V.) Further, a first control signal φ1 and a second control signal φ2 having a phase opposite to each other are intersectionally applied to the first and second switches M1 and M2, respectively. For example, after the first control signal φ1 is applied to the first switch M1 and the second control signal φ2 is applied to the second switch M2, and the second control signal φ2 is applied to the first switch M1, and the first control signal φ1 is applied to the second switch M2. The first control signal φ1 is applied to the third and fifth switches M3 and M5, and the second control signal φ2 is applied to the fourth switch M4. The first control signal φ1 and the second control signal φ2 control an On/Off operation of the switches provided in the amplifier 540.

A driving method of the amplifier 540 in an implementation is described in detail hereinafter with reference to the accompanying drawings.

First, the first control signal φ1 is applied to the first switch M1, the third switch M3, and the fifth switch M5, and the second control signal φ2 is applied to the second switch M2 and the fourth switch M4.

<Case 1> In the case of the first control signal φ1 is in a high state and the second control signal φ2 is in a low state, the first switch M1 is turned on and the second switch M2 is turned off. Accordingly, a reference voltage V_{REF}* selected in the selection switch unit 530 is charged at one end of the first capacitor C1. The other end of the first capacitor C1 is connected to an inversion terminal of the output buffer 541. Accordingly, the first voltage V1 and an offset voltage V_{offset} are charged at the other end of the first capacitor C1 by turning on the third switch M3 provided in a feedback path of between an inversion terminal and the output terminal of an output buffer 541. Therefore, a voltage charged in the first capacitor C1 is represented by Equation 1.

V_{C1}=(V_{REF}*)−(V1+V_{offset}) [Equation 1]

‘V_{C1}’ of Equation 1 indicates a voltage charged in the first capacitor C1, ‘V_{REF}*’ indicates a reference voltage, ‘V1’ indicates a first voltage V1, and ‘V_{offset}’ indicates an offset voltage V_{offset} of the output buffer 541. Electric charges Q_{C1} charged in the first capacitor C1 are represented by Equation 2.

Q_{C1}=C1×[(V_{REF}*)−(V1+V_{offset})] [Equation 2]

‘Q_{C1}’ of Equation 2 indicates electric charges charged in the first capacitor C1 and ‘C1’ indicates capacitance of the first capacitor C1. One end of the second capacitor C2 is connected to an inversion terminal of the output buffer 541. Accordingly, an offset voltage V_{offset} and the first voltage V1 are charged at one end of the second capacitor C2. The first voltage V1 is charged at the other end of the second capacitor C2 by turning on the fifth switch M5. Because the fourth switch M4 receives the second control signal φ2 in a low state, the fourth switch M4 is turned off. Therefore, a voltage charged in the second capacitor C2 is represented by Equation 3.

$$\begin{matrix}{V}_{C 2} = V 1 - ( V 1 + {V}_{offset} ) \\ = - {V}_{offset}\end{matrix} \qquad [ Equation 3 ]$$

‘V_{C2}’ of Equation 3 indicates a voltage charged in the second capacitor C2, ‘V1’ indicates a first voltage, and ‘V_{offset}’ indicates an offset voltage V_{offset} of the output buffer 541. Therefore, an offset voltage V_{offset} of the output buffer 541 is charged in the second capacitor C2. Electric charges charged in the second capacitor C2 are represented by Equation 4.

Q_{C2}=C2×(−V_{offset}) [Equation 4]

‘Q_{C2}’ of Equation 4 indicates electric charges charged in the second capacitor and ‘C2’ indicates capacitance of the second capacitor C2.

<Case 2> In the case of the first control signal φ1 is in a low state and the second control signal φ2 is in a high state, the first switch M1 is turned off and the second switch M2 is turned on. The other end of the second switch M2 is grounded (0V), as shown in FIG. 6. Therefore, a ground voltage (0V) is charged at one end of the first capacitor C1. The other end of the first capacitor C1 is connected to the inversion terminal of the output buffer 541. Accordingly, an offset voltage V_{offset} is added to the first voltage V1 detected at the output buffer 541. Accordingly an offset voltage V_{offset} and the first voltage V1 are charged at the other end of the second capacitor C1. Accordingly, a voltage charged in the first capacitor C1 is represented by Equation 5.

V_{C1}′=−(V1+V_{offset}) [Equation 5]

‘V_{C1}′’ of Equation 5 indicates a voltage charged in the first capacitor C1, ‘V1’ indicates a first voltage V1, and ‘V_{offset}’ indicates an offset voltage V_{offset} of the output buffer 541. Electric charges Q_{C1}′ charged in the first capacitor C1 are represented by Equation 6.

Q_{C1}′=C1×[−(V1+V_{offset})] [Equation 6]

‘Q_{C1}′’ of Equation 6 indicates electric charges charged in the first capacitor C1, and ‘C1’ indicates capacitance of the first capacitor C1. The fifth switch M5 is turned off when the first control signal φ1 becomes a low state. However, because the fourth switch M4 receives the second control signal φ2 in a high state, the fourth switch M4 is turned on. A voltage detected at the other end of the second capacitor C2 sames an output voltage outputted from the output terminal of the output buffer 541. The output voltage is represented with a first output voltage V_{channel1}. One end of the second capacitor C2 is connected to the inversion terminal of the output buffer 541. Accordingly, an offset voltage V_{offset} and the first voltage V1 are charged at one end of the second capacitor C2. Therefore, a voltage charged in the second capacitor C2 is represented by Equation 7.

V_{C2}′=[V_{channel1}−(V1+V_{offset})] [Equation 7]

V_{C2}′ of Equation 7 indicates a voltage charged in the second capacitor C2, ‘V_{channel1}’ indicates a first output voltage V_{channel1} output from the amplifier 540. Electric charges Q_{C2}′ charged in the second capacitor C2 are represented by Equation 8.

Q_{C2}′=C2×[V_{channel1}−(V1+V_{offset})] [Equation 8]

‘Q_{C2}′’ of Equation 8 indicates electric charges charged in the second capacitor C2 and ‘C2’ indicates capacitance of the second capacitor C2. Total electric charges charged in the first capacitor C1 and the second capacitor C2 according to a state of the first control signal φ1 and the second control signal φ2 are represented by Equation 9.

Q_{C1}+Q_{C2}=Q_{C1}′+Q_{C2}′ [Equation 9]

In Equation 9, a left Equation Q_{C1}+Q_{C2} indicates total electric charges charged in the first capacitor C1 and the second capacitor C2 according to <Case 1>. A right Equation Q_{C1}′+Q_{C2}′ indicates total electric charges charged in the first capacitor C1 and the second capacitor C2 according to <Case 2>. Therefore, Equation 9 may be represented with Equation 10 using Equations 2, 4, 6, and 8.

$$\begin{matrix}[ C 1 \times ( ( {V}_{REF}^{*} ) - ( V 1 + {V}_{offset} ) ] + \\ [ C 2 \times ( - {V}_{offset} ) ]\end{matrix} = \begin{matrix}[ C 1 \times ( - ( V 1 + {V}_{offset} ) ) ] + \\ [ C 2 \times ( {V}_{Channel 1} - ( V 1 + {V}_{offset} ) ) ]\end{matrix} \qquad [ Equation 10 ]$$

The first output voltage V_{channel1} may be represented with Equation 11 using Equation 10.

$${V}_{channel 1} = V 1 + ( \frac{C 1}{C 2} ) \times ( {V}_{REF}^{*} ) \qquad [ Equation 11 ]$$

Referring to Equation 11, a reference voltage V_{REF}* can be amplified according to capacitance of the first and second capacitors C1 and C2. Therefore, In the case of the first voltage V1 is applied to the fifth switch M5, capacitance of the first capacitor C1 is set to be greater by K/2 times than that of the second capacitor C2. Accordingly, the amplifier 540 performing processes of <Case 1> and <Case 2> amplifies the reference voltage V_{REF}* by K/2 times, and outputs a first output voltage V_{channel1} in which the amplified reference voltage is added to the first voltage V1. In the case of the first voltage V1 is 0V (ground), a capacitance of the first capacitor C1 is set to be greater by K times than that of the second capacitor C2 and thus the amplifier 540 can output the first output voltage V_{channel1} amplified by K times the reference voltage V_{REF}*.

In a second case, the first control signal φ1 is applied to the second switch M2, the third switch M3, and the fifth switch M5, and the second control signal φ2 is applied to the first switch M1 and the fourth switch M4. the first voltage V1 applied to the other end of the fifth switch M5 and the non-inversion terminal of the output buffer 541 in the amplifier 540 is negative gamma voltage.

<Case 3> In the case of the first control signal φ1 is in a high state and the second control signal φ2 is in a low state, the first switch M1 is turned off and the second switch M2 is turned on. Because the other end of the second switch M2 is grounded, a ground voltage (0V) is charged at one end of the first capacitor C1. Third switch M3 is turned on. Accordingly, an offset voltage V_{offset} and the first voltage V1 (Negative Gamma voltage) are charged at the other end of the first capacitor C1 by turning on the third switch M3. Therefore, a voltage charged in the first capacitor C1 is represented by Equation 12.

V_{C1}=−(V1+V_{offset}) [Equation 12]

‘V_{C1}’ of Equation 12 indicates a voltage charged in the first capacitor C1, ‘V1’ indicates the first voltage V1 (Negative Gamma voltage), and ‘V_{offset}’ indicates an offset voltage V_{offset} of the output buffer 541. Electric charges Q_{C1} charged in the first capacitor C1 are represented by Equation 13.

Q_{C1}=C1×[−(V1+V_{offset})] [Equation 13]

‘Q_{C1}’ of Equation 13 indicates electric charges charged in the first capacitor C1, and ‘C1’ indicates capacitance of the first capacitor C1. Further, One end of the second capacitor C2 is connected to the inversion terminal of the output buffer 541. Accordingly, an offset voltage V_{offset} and the first voltage (Negative Gamma voltage) V1 are charged at one end of the second capacitor C2. The first voltage V1 (Negative Gamma voltage) is charged at the other end of the second capacitor C2 by turning on the fifth switch M5. Because the fourth switch M4 receives the second control signal φ2 in a low state, the fourth switch M4 is turned off. Accordingly, a voltage charged in the second capacitor C2 is represented by Equation 14.

$$\begin{matrix}{V}_{C 2} = V 1 - ( V 1 + {V}_{offset} ) \\ = - {V}_{offset}\end{matrix} \qquad [ Equation 14 ]$$

Electric charges Q_{C2} charged in the second capacitor C2 are represented by Equation 15.

Q_{C2}=C2×(−V_{offset}) [Equation 15]

‘Q_{C2}’ of Equation 15 indicates electric charges charged in the second capacitor C2 and ‘C2’ indicates capacitance of the second capacitor C2.

<Case 4> In the case of the first control signal φ1 is in a low state and the second control signal φ2 is in a high state, the first switch M1 is turned on and the second switch M2 is turned off. Accordingly, a reference voltage V_{REF}* selected in the selection switch unit 530 is charged at one end of the first capacitor C1. The other end of the first capacitor C1 is connected to the inversion terminal of the output buffer 541. Accordingly, an offset voltage V_{offset} of the output buffer 54L and the first voltage V1 (Negative Gamma voltage) are charged at the other end of the first capacitor C1. Therefore, a voltage charged in the first capacitor C1 is represented by Equation 16.

V_{C1}′=(V_{REF}* )−(V1+V_{offset}) Equation 16

‘V_{C1}′’ of Equation 16 indicates a voltage charged in the first capacitor C1. Electric charges Q_{C1} charged in the first capacitor C1 are represented by Equation 17.

Q_{C1}′=C1×[(V_{REF}*)−(V1+V_{offset})] [Equation 17]

‘Q_{C1}′’ of Equation 17 indicates electric charges charged in the first capacitor C1 and ‘C1’ indicates capacitance of the first capacitor C1. Further, The inversion terminal of the output buffer 541 is connected to one end of the second capacitor C2. Accordingly, an offset voltage V_{offset} and the first voltage V1 (Negative Gamma voltage) are charged at one end of the first capacitor C1. Because the fifth switch M5 connected to the other end of the second capacitor C2 receives the first control signal φ1 in a low state, the fifth switch M5 is turned off. Because the fourth switch M4 receives the second control signal φ2 in a high state, the fourth switch M4 is turned on. Accordingly, an output voltage of the output buffer 541 is detected at the other end of the second capacitor C2. Here, the output voltage is represented with a second output voltage V_{channel2}. One end of the second capacitor C2 is connected to the inversion terminal of the output buffer 541, Accordingly, an offset voltage V_{offset} and the first voltage V1 (Negative Gamma voltage) are charged at the one end of the second capacitor C2. Therefore, a voltage charged in the second capacitor C2 is represented by Equation 18.

V_{C2}′=[V_{channel2}−(V1+V_{offset})] [Equation 18]

‘V_{C2}′’ of Equation 18 indicates a voltage charged in the second capacitor C2. Electric charges Q_{C2}′ charged in the second capacitor C2 are represented by Equation 19.

Q_{C2}′=C2×[V_{channel2}−(V1+V_{offset})] [Equation 19]

‘Q_{C2}′’ of Equation 19 indicates electric charges charged in the second capacitor C2 and ‘C2’ indicates capacitance of the second capacitor C2. According to a state of the first control signal φ1 and the second control signal φ2, total electric charges charged in the first capacitor C1 and the second capacitor C2 are represented by Equation 20.

Q_{C1}+Q_{C2}=Q_{C1}′+Q_{C2}′ [Equation 20]

In Equation 20, a left Equation Q_{C1}+Q_{C2} indicates total electric charges of the first capacitor C1 and the second capacitor C2 for performing <Case 3>. A right Equation Q_{C1}′+Q_{C2}′ indicates total electric charges charged in the first capacitor C1 and the second capacitor C2 for performing <Case 4>. Therefore, Equation 20 may be represented with Equation 21 using Equation 13, 15, 17, and 18.

[C1×(−(V1+V_{offset}))]+[C2×(−V_{offset})]=[C1×((V_{REF}*)−(V1+V_{offset}))]+[C2×(V_{Channel2}−(V1+V_{offset}))] [Equation 21]

The second output voltage V_{channel2} may be represented by Equation 22 using Equation 21.

$${V}_{channel 2} = V 1 - ( \frac{C 1}{C 2} ) \times ( {V}_{REF}^{*} ) \qquad [ Equation 22 ]$$

Referring to Equation 22, a reference voltage V_{REF}* can be amplified according to setting of capacitance of the first capacitor C1 and the second capacitor C2. Therefore, when the first voltage V1 (Negative Gamma Voltage) is applied to the fifth switch M5, capacitance of the first capacitor C1 can be set to be greater by K/2 times than that of the second capacitor C2. Accordingly, the amplifier 540 amplifies a reference voltage V_{REF}* by K/2 times, and outputs a second output voltage V_{channel2} in which the amplified reference voltage is subtracted from the first voltage V1 (Negative Gamma Voltage).

Therefore, the driving apparatus for a display in implementation is driven with a low-level of voltages however the driving apparatus for a display in implementation can driven equally to a driving apparatus for a display driven in a level of a source voltage used in a buffer amplifier for output driving by an amplification function of the amplifier 540. Accordingly, because many circuit elements of the decoder 520 and the selection switch 530 comprised in the digital/analog converter 500 is driven with a low-level of voltage, a size of elements can be reduced. The digital/analog converter 500 and the amplifier 540 perform a function of a level shifter for amplifying a low input voltage. Accordingly, in the driving apparatus for a display in an implementation, because the level shifter can be deleted, an entire circuit area can be further reduced.

FIG. 7 is a diagram illustrating a first voltage additional circuit 550 provided in the amplifier 540.

Referring to FIG. 7, the first voltage additional circuit 550 comprises a third capacitor C3 whose one end is connected to the other end of the second capacitor C2, a sixth switch M6 whose one end is connected to the other end of the third capacitor C3, and a seventh switch M7 whose one end is connected to the other end of the third capacitor C3. The first control signal φ1 and the second control signal φ2 are applied to intersect the sixth and seventh switches M6 and M7, respectively. For example, after the first control signal φ1 is applied to the sixth switch M6 and the second control signal φ2 is applied to the seventh switch M7, the second control signal φ2 is applied to the sixth switch M6, and the first control signal φ1 is applied to the seventh switch M7. It is preferable that the second voltage V2 corresponding to the N bit data signal among a data signal of an (M+N) bit in which an N (N is a positive integer) bit is added to an M bit is applied to the other end of the sixth switch M6.

A driving method of the first voltage additional circuit 550 and the amplifier 540 according to a state of the first control signal φ1 and the second control signal φ2 is described hereinafter.

In a first case, the first control signal φ1 is applied to the sixth switch M6 and the second control signal φ2 is applied to the seventh switch M7.

<Case 1-1> When the first: control signal φ1 is in a high state and the second control signal φ2 is in a low state, the sixth switch M6 is turned on and the seventh switch M7 is turned off. Accordingly, the second voltage V2 applied to the other end of the sixth switch M6 is charged at the other end of the third capacitor C3. One end of the third capacitor C3 is connected to the inversion terminal of the output buffer 541. Accordingly, an offset voltage V_{offset} and the first voltage V1 are charged at one end of the third capacitor C3. Therefore, a voltage charged in the third capacitor C3 is represented by Equation 23.

V_{C3}=V2−(V1+V_{offset}) Equation 23

‘V_{C3}’ of Equation 23 indicates a voltage charged in the third capacitor C3. Further, electric charges Q_{C3} charged in the third capacitor C3 are represented by Equation 24.

Q_{C3}=C3×[V2−(V1+V_{offset})] [Equation 24]

‘Q_{C3}’ of Equation 24 indicates electric charges charged in the third capacitor C3 and ‘C3’ indicates capacitance of the third capacitor C3.

<Case 2-1> When the first control signal φ1 is in a low state and the second control signal φ2 is in a high state, the sixth switch M6 is turned off and the seventh switch M7 is turned on. As shown in FIG. 7, the other end of the seventh switch M7 is grounded. Accordingly, an offset voltage V_{offset} and the first voltage V1 are charged at one end of the seventh switch M7. Accordingly, a voltage charged in the third capacitor C3 is represented by Equation 25.

V_{C3}′=−(V1+V_{offset}) [Equation 25]

‘V_{C3}’ of Equation 25 indicates a voltage charged in the third capacitor C3. Electric charges Q_{C3}′ charged in the third capacitor C3 are represented by Equation 26.

Q_{C3}′=C3×[−(V1+V_{offset})] [Equation 26]

‘Q_{C3}′’ of Equation 26 indicates electric charges of the third capacitor C3 and ‘C3’ indicates capacitance of the third capacitor C3. Total electric charges of the first, second, and third capacitors C1, C2, and C3 according to a state change of the first control signal φ1 and the second control signal φ2 are represented by Equation 27.

Q_{C1}+Q_{C2}+Q_{C3}=Q_{C1}′+Q_{C2}′+Q_{C3}′ [Equation 27]

In Equation 27, a left Equation Q_{C1}+Q_{C2}+Q_{C3} indicates total electric charges charged in the first, second and third capacitors C1, C2, and C3 after performing <Case 1> and <Case 1-1>. Further, a right Equation Q_{C1}′+Q_{C2}′+Q_{C3}′ indicates total electric charges charged in the first, second, and third capacitors C1, C2, and C3 after performing <Case 2> and <Case 2-1>. Therefore, Equation 27 may be represented with Equation 28 using Equation 9, Equation 24, and Equation 26.

$$[ C 1 \times ( ( {V}_{REF}^{*} ) - ( V 1 + {V}_{offset} ) ] + [ C 2 \times ( - {V}_{offset} ) ] + C 3 \times [ V 2 - ( V 1 + {V}_{offset} ) ] = [ C 1 \times ( - ( V 1 + {V}_{offset} ) ) ] + [ C 2 \times ( {V}_{channel 3} - ( V 1 + {V}_{offset} ) ) ] + C 3 \times [ - ( V 1 + {V}_{offset} ) ] \qquad [ Equation 28 ]$$

The third output voltage V_{channel3} of Equation 28 indicates an output voltage detected in the output terminal of the output buffer 541 after performing <Case 1>, <Case 1-1>, <Case 2>, and <Case 2-1>. The third output voltage V_{channel3} may be represented by Equation 29 using Equation 28.

$$\begin{matrix}{V}_{channel 3} = V 1 + ( \frac{C 1}{C 2} ) \times ( {V}_{REF}^{*} ) + ( \frac{C 3}{C 2} ) \times V 2 \\ = {V}_{channel 1} + ( \frac{C 3}{C 2} ) \times V 2\end{matrix} \qquad [ Equation 29 ]$$

Referring to Equation 29, the amplifier 540 outputs the third output voltage V_{channel3} in which the second voltage V2 is added to the first output voltage V_{channel1}. A magnitude of the second voltage V2 can be adjusted according to setting of capacitance of the second capacitor C2 and the third capacitor C3. Therefore, the amplifier 540 in which the first voltage additional circuit 550 is additionally provided outputs the third output voltage V_{channel3} in which the second voltage V2 corresponding to the N (N is a positive integer) bit data signal among a data signal of an (M+N) bit in which an N bit is added to an M bit is added to the first output voltage V_{channel1}.

In a second case, the second control signal φ2 is applied to the sixth switch M6 and the first control signal φ1 is applied to the seventh switch M7.

<Case 3-1> When the first control signal φ1 is in a high state and the second control signal φ1 is in a low state, the sixth switch M6 is turned off and the seventh switch M7 is turned on. As shown in FIG. 7, the other end of the seventh switch M7 is grounded. One end of the third capacitor C3 is connected to the inversion terminal of the output buffer 541. Accordingly, an offset voltage V_{offset} and the first voltage V1 are charged at one end of the third capacitor C3. Therefore, a voltage charged in the third capacitor C3 is represented by Equation 30.

V_{C3}=−(V1+V_{offset}) [Equation 30]

‘V_{C3}’ of Equation 30 indicates a voltage charged in the third capacitor C3. Electric charges Q_{C3} charged in the third capacitor C3 are represented by Equation 31.

Q_{C3}=C3×[−(V1+V_{offset})] [Equation 31]

‘Q_{C3}’ of Equation 31 indicates electric charges charged in the third capacitor C3 and ‘C3’ indicates capacitance of the third capacitor C3.

<Case 4-1> When the first control signal φ1 is in a low state and the second control signal φ2 is in a high state, the sixth switch M6 is turned on and the seventh switch M7 is turned off. Accordingly, the second voltage V2 applied to the other end of the sixth switch M6 is charged at the other end of the third capacitor C3. One end of the third capacitor C3 is connected to the inversion terminal of the output buffer 541. Accordingly, the first voltage V1 are an offset voltage V_{offset} are charged at one end of the third capacitor C3. Therefore, a voltage charged in the third capacitor C3 is represented by Equation 32.

V_{C3}′=V2−(V1+V_{offset}) [Equation 32]

‘V_{C3}′’ of Equation 32 indicates a voltage charged in the third capacitor C3. Electric charges Q_{C3}′ charged in the third capacitor C3 are represented by Equation 33.

Q_{C3}′=C3×[V2−(V1+V_{offset})] [Equation 33]

‘Q_{C3}′’ of Equation 33 indicates electric charges charged in the third capacitor C3 and ‘C3’ indicates capacitance of the third capacitor C3. Therefore, total electric charges of the first capacitor C1, the second capacitor C2, and the third capacitor C3 are represented by Equation 34.

Q_{C1}+Q_{C2}+Q_{C3}=Q_{C1}′+Q_{C2}′+Q_{C3}′ [Equation 34]

In Equation 34, a left Equation Q_{C1}+Q_{C2}+Q_{C3} indicates total electric charges charged in the first, second and third capacitors C1, C2, and C3 after performing <Case 3> and <Case 3-1>. A right Equation Q_{C1}′+Q_{C2}′+Q_{C3}′ indicates total electric charges charged in the first, second and third capacitors C1, C2, and C3 after performing <Case 4> and <Case 4-1>. Therefore, Equation 34 may be represented with Equation 35 using Equation 20, Equation 31, and Equation 33.

[C1×(−(V1+V_{offset}))]+[C2×(−V_{offset})]+C3×[−(V1+V_{offset})]=[C1×((V_{REF}*)−(V1+V_{offset}))]+[C2×(V_{channel4}−(V1+V_{offset}))]+C3×[V2−(V+V_{offset})] [Equation 35]

A fourth output voltage V_{channel4} of Equation 35 indicates an output voltage detected in the output terminal of the output buffer 541 after performing <Case 3>, <Case 3-1>, <Case 4>, and <Case 4-1>. The fourth output voltage V_{channel4} may be represented by Equation 36 using Equation 35.

$$\begin{matrix}{V}_{channel 4} = V 1 - ( \frac{C 1}{C 2} ) \times ( {V}_{REF}^{*} ) - ( \frac{C 3}{C 2} ) \times V 2 \\ = {V}_{channel 2} - ( \frac{C 3}{C 2} ) \times V 2\end{matrix} \qquad [ Equation 36 ]$$

Referring to Equation 36, the amplifier 540 outputs a fourth output voltage V_{channel4} (Negative Gamma Voltage) in which the second voltage V2 is subtracted from the second output voltage V_{channel2} (Negative Gamma Voltage). A magnitude of the second voltage V2 can be adjusted according to setting of capacitance of the second capacitor C2 and the third capacitor C3. Therefore, the amplifier 540 in which the first voltage additional circuit 550 is additionally provided outputs the fourth output voltage V_{channel3} (Negative Gamma voltage) in which the second voltage V2 corresponding to the N bit data signal among an (M+N) bit data signal is subtracted from the second output voltage V_{channel2} (Negative Gamma Voltage). Therefore, the first voltage additional circuit 550 and the amplifier 540 can further divide a level of an output voltage corresponding to 2^{M} data signals by an N bit. Accordingly, resolution of a driving apparatus for a display can be increased while sustaining an area of the decoder 520 and the selective switch 530 to the minimum.

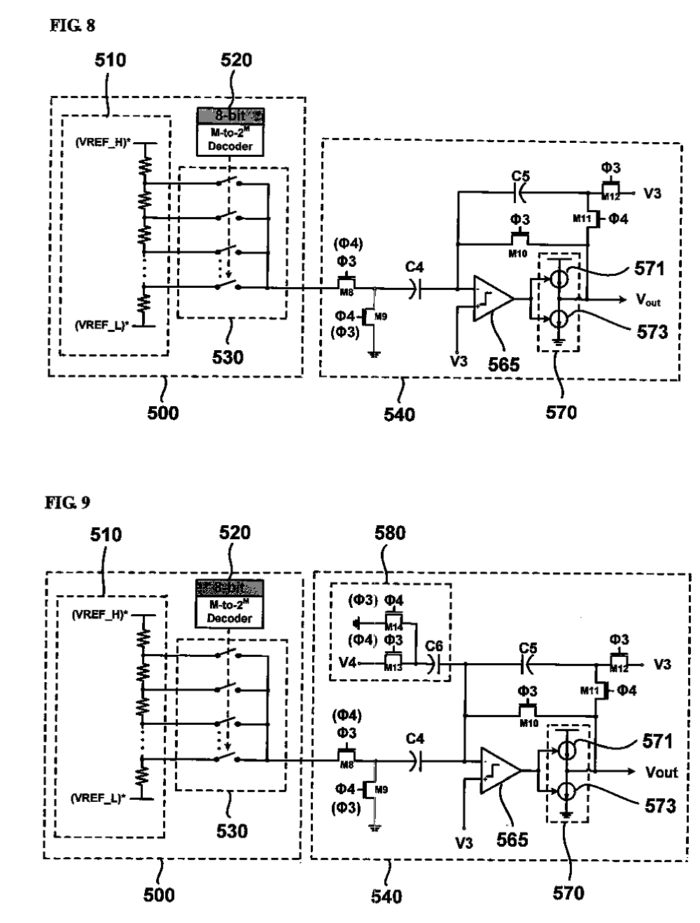

FIG. 8 is a diagram illustrating the amplifier 540 in another implementation. The amplifier 540 in another implementation is described with reference to the accompanying drawings.

Referring to FIG. 8, the amplifier 540 comprises an eighth switch M8 in which a reverence voltage selected by the digital/analog converter 600 is applied at one end thereof, a ninth switch M9 whose one end is connected to the other end of the eighth switch M8, a fourth capacitor C4 whose one end is connected to one end of the ninth switch M9, a tenth switch MIC whose one end is connected to the other end of the fourth capacitor C4, a fifth capacitor C5 whose one end is connected to one end of the tenth switch M10, an eleventh switch M11 whose one end is connected to the other end of the fifth capacitor C5 and whose the other end is connected to the other end of tenth switch M10, a twelfth switch M12 whose one end is connected to one end of the eleventh switch M11, a comparator 565 whose inversion terminal is connected to the other end of the fourth capacitor C4 and for comparing magnitudes of voltages detected in a non-inversion terminal and the inversion terminal and for outputting a comparison signal, and a current power source 570 for controlling a direction of a current flowing to the fourth capacitor C4 and the fifth capacitor C5 according to a comparison signal.

The current power source 570 comprises a first current power source 571 for outputting a current in a direction of the fourth and fifth capacitors C4 and C5 from the current power source 570 and a second current power source 573 for outputting a current in a direction of the current power source 570 from the fourth and fifth capacitors C4 and C5, according to a comparison signal of the comparator 565. The comparator 565 compares magnitudes of voltages detected in the inversion terminal and the non-inversion terminal and outputs a comparison signal to the current power source 570. The output comparison signal drives the first current power source 571 or the second current power source 573. For example, when a voltage detected in the non-inversion terminal of the comparator 565 is greater than that detected in the inversion terminal, the first current power source 571 is driven and thus a current flows in a direction of the fourth capacitor C4 from the fifth capacitor C5. When a magnitude of a voltage detected in the inversion terminal is large, the second current power source 573 is driven and thus a current flows in a direction of the fifth capacitor C5 from the fourth capacitor C4. Further, when magnitudes of voltages detected in the inversion terminal and the non-inversion terminal are equal, the current power source 570 is turned off.

It is preferable that a third voltage V3, which is a half of a source voltage (about 12V to 18V) is applied to the other end of the twelfth switch M12 and the non-inversion terminal of the output buffer 541. Further, the third control signal φ3 and the fourth control signal φ4 having a phase opposite to each other are applied to intersect the eighth and ninth switches M8 and M9, respectively. For example, after the third control signal φ3 is applied to the eighth switch M8 and the fourth control signal φ4 is applied to the ninth switch M9, the fourth control signal φ4 is applied to the eighth switch M8, and the third control signal φ3 is applied to the ninth switch M9. The third control signal φ3 is applied to the tenth and twelfth switches M10 and M12, and the fourth control signal φ4 is applied to the eleventh switch M11.

A driving method of the amplifier 540 according to the third and fourth control signals φ3 and φ4 is described hereinafter.

In a first case, the third control signal φ3 is applied to the eighth switch M8, the tenth switch M10, and the twelfth switch M12, and the fourth control signal φ4 is applied to the ninth switch M9 and the eleventh switch M11.

<Case 5> When the third control signal φ3 is in a high state and the fourth control signal φ4 is in a low state, the eighth switch M8 is turned on and the ninth switch M9 is turned off. Accordingly, a reference voltage V_{REF}* selected from the selection switch 530 is charged at one end of the fourth capacitor C4. The other end of the fourth capacitor C4 is connected to the inversion terminal of the comparator 565. Accordingly, an offset voltage V_{offset} is added to the third voltage V3 is charged at the other end of the fourth capacitor C4 by turning on the tenth switch M10 provided in a feedback path between the inversion terminal and an output terminal of the comparator 565. The inversion terminal of the comparator 565 is connected at one end of the fifth capacitor C5. Accordingly, an offset voltage V_{offset} and the third voltage V3 are charged at one end of the fifth capacitor C5. The twelfth switch M12 for receiving the third voltage V3 is turned on by the third control signal φ3. Accordingly, the third voltage V3 is charged at the other end of the fifth capacitor C5. Accordingly, the current power source 570 is turned off.

<Case 6> When the third control signal φ3 is in a low state and the fourth control signal φ4 is in a high state, the eighth switch M8 is turned off and the ninth switch M9 is turned on. The other end of the ninth switch M9 is grounded. Accordingly, a reference voltage V_{REF}* charged at one end of the fourth capacitor C4 is discharged to a ground voltage (0V), and a voltage of the other end of the fourth capacitor C4 also decreases by a reference voltage V_{REF}*. Accordingly, a magnitude of a voltage detected in the inversion terminal of the comparator 565 is lower than that of a voltage detected in the non-inversion terminal fixed to the third voltage V3. Therefore, the comparator 565 outputs a comparison signal for driving the first current power source 571. A current output from the first current power source 571 flows in a direction of the fourth capacitor C4 from the fifth capacitor C5 by turning on the eleventh switch M11 received the fourth control signal φ4 in a high state. A voltage starts to be charged in the fourth capacitor C4 and the fifth capacitor C5 by a current output from the first current power source 571. Thereafter, if a voltage of the other end of the fourth capacitor C4 increases to a voltage of the non-inversion terminal of the comparator, the current power source 570 is turned off. Accordingly, the same amount of voltage as the decreased reference voltage V_{REF}* is charged at the other end of the fourth capacitor C4. A voltage change at both ends of the fourth capacitor C4 is represented by Equation 37.

$$Δ {V}_{C 4} = \frac{1}{C 4} {\int }_{0}^{t} I d t \qquad [ Equation 37 ]$$

‘ΔV_{C4}’ of Equation 37 indicates a voltage change amount at both ends of the fourth capacitor C4, ‘C4’ indicates capacitance of the fourth capacitor C4, and ‘I’ indicates a current flowing to the fourth capacitor C4. The voltage change amount at both ends of the fourth capacitor C4 indicates a voltage ΔV_{C4} charged in the fourth capacitor C4. The charged voltage ΔV_{C4} is in inversely proportion to capacitance of the fourth capacitor C4. As shown in FIG. 8, because the fourth and fifth capacitors C4 and C5 are connected in series, an amount of a current I flowing to each capacitor is equal. When capacitance of the fourth capacitor C4 is set to be greater by K times than that of the fifth capacitor C5, a voltage of the same amount as a reference voltage V_{REF}* is charged in the fourth capacitor C4, and a reference voltage amplified by K times is charged in the fifth capacitor C5. Therefore, a voltage change in the fifth capacitor C5 is represented by Equation 38.

$$\begin{matrix}Δ {V}_{C 5} = \frac{1}{C 5} {\int }_{0}^{t} I d t \\ = \frac{1}{C 4 \times \frac{1}{K}} {\int }_{0}^{t} I d t \\ = K \times Δ {V}_{C 4}\end{matrix} \qquad [ Equation 38 ]$$

Referring to Equation 38, a voltage change amount ΔV_{C5} charged in the fifth capacitor C5 is greater by K times than a voltage change amount ΔV_{C1} of the fourth capacitor C4. That is, a reference voltage V_{REF}* is amplified by K times and charged in the fifth capacitor C5. When the third voltage V3 is applied to the other end of the twelfth switch M12, capacitance of the fourth capacitor C4 is set to be greater by K/2 times than capacitance of the fifth capacitor C5. Accordingly, the amplifier 540 amplifies the reference voltage V_{REF}* by K/2 times, and a fifth output voltage in which the amplified reference voltage is added to the third voltage V3 is output. Therefore, when the third voltage V3 is not applied, by setting capacitance of the fourth capacitor C4 to be greater by K times than that of the fifth capacitor C5, a fifth output voltage amplified by K times than the reference voltage V_{REF}* can be output.

In a second case, when the third control signal φ3 is applied to the ninth switch M9, the tenth switch M10, and the twelfth switch M12, and the fourth control signal φ4 is applied to the eighth switch M5 and the eleventh switch M11.

<Case 7> When the third control signals φ3 is in a high state and the fourth control signals φ4 is in a low state, the eighth switch M8 is turned off and the ninth switch M9 is turned on. Accordingly, a ground voltage (0V) is charged at one end of the fourth capacitor C4. The tenth switch M10 provided in a feedback path between the inversion terminal and the output terminal of the comparator 565 is turned on. Accordingly, an offset voltage V_{offset} and the third voltage V3 (Negative Gamma voltage) are charged at the other end of the fourth capacitor C4. One end of the fifth capacitor C5 is connected to the inversion terminal of the comparator 565. Accordingly, an offset voltage V_{offset} and the third voltage V3 (Negative Gamma voltage) are charged at One end of the fifth capacitor C5. The twelfth switch M12 applied to the third voltage V3 (Negative Gamma voltage) is turned on by the third control signal φ3, and thus the third voltage V3 (Negative Gamma Voltage) is charged at the other end of the fifth capacitor C5. Accordingly, the current power source 570 is in a turn-off state.

<Case 8> In the case of the third control signal φ3 is in a low state and the fourth control signal φ4 is in a high state, the eighth switch ME is turned on and the ninth switch M9 is turned off. Accordingly, a reference voltage V_{REF}* selected from the selection switch 530 is charged at one end of the fourth capacitor C4. Accordingly, a reference voltage V_{REF}*, the third voltage V3 (Negative Gamma voltage) and the offset voltage V_{offset} are charged at the other end of the fourth capacitor C4. Therefore, a voltage detected at the other end of the fourth capacitor C4 is higher than that detected at the non-inversion terminal received the third voltage V3 (Negative Gamma voltage). Accordingly, the comparator 565 outputs a comparison signal for driving the second current power source 573. A current flows from the fourth and fifth capacitors C4 and C5 to the current power source 570 by the second current power source 573. As a current flows from one end to the other end of the fourth capacitor C4, a voltage of the other end thereof starts to decrease. A voltage of one end of the fourth capacitor C4 is fixed to a reference voltage V_{REF}*, and a voltage detected in the non-inversion terminal decreases. When a voltage of the inversion terminal of the comparator 565 becomes equal to that of the non-inversion terminal thereof, the second current power source 573 is turned off. Therefore, a total voltage of the fourth capacitor C4 decreases by the second current power source 573. A voltage change amount decreased in the fourth capacitor C4 is represented by Equation 39.

$$- Δ {V}_{C 4}^{′} = - \frac{1}{C 4} {\int }_{0}^{t} I d t \qquad [ Equation 39 ]$$

‘−ΔV_{C4}’ of Equation 39 indicates a voltage decrease amount in the fourth capacitor C4. The voltage decrease amount −ΔV_{C4}′ is in inversely proportion to capacitance of the fourth capacitor C4. As shown in FIG. 8, because the fourth and fifth capacitors C4 and C5 are connected in series, a current I amount flowing to each capacitor is equal. In the case of capacitance of the fourth capacitor C4 is set to be greater by K time than that of the fifth capacitor C5, while the fourth capacitor C4 discharges by a reference voltage V_{REF}*, a voltage amplified by K times is discharged to the fifth capacitor C5. Therefore, a discharged voltage of the fifth capacitor C5 is represented by Equation 40.

$$\begin{matrix}- Δ {V}_{C 5} = - \frac{1}{C 5} {\int }_{0}^{t} I d t \\ = - \frac{1}{C 5 \times \frac{1}{K}} {\int }_{0}^{t} I d t \\ = - K \times Δ {V}_{C 4}\end{matrix} \qquad [ Equation 40 ]$$

Referring to Equation 40, a voltage decrease amount −ΔV_{C5} of the fifth capacitor C5 is greater by K times than a voltage decrease amount −ΔV_{C1} of the fourth capacitor C4. That is, a voltage V in which the reference voltage V_{REF}* is amplified by K times is discharged at the fifth capacitor C5. As another method, In the case of the third voltage V3 (Negative Gamma voltage) is applied to the other end of the twelfth switch M12, capacitance of the fourth capacitor C4 is set to be greater by K/2 times than that of the fifth capacitor C5. Accordingly, the amplifier 540 outputs a sixth output voltage in which a reference voltage amplified by K/2 times is subtracted from the third voltage V3.

FIG. 9 is a diagram illustrating the second voltage additional circuit 580 additionally provided in the amplifier 540.

Referring to FIG. 9, the second voltage additional circuit 580 comprises a sixth capacitor C6 whose one end is connected to one end of the fifth capacitor C5, a thirteenth switch M13 whose one end is connected to the other end of the sixth capacitor C6, and a fourteenth switch M14 whose one end is connected to the other end of the sixth capacitor C6. The third control signal φ3 and the fourth control signal φ4 are intersectionally applied to the thirteenth switch M13 and the fourteenth switch M14, respectively. For example, after the third control signal 43 is applied to the thirteenth switch M13 and the fourth control signal φ4 is applied to the fourteenth switch M14, the fourth control signal φ4 is applied to the thirteenth switch M13, and the third control signal φ3 is applied to the fourteenth switch M14. The fourth voltage V4 corresponding to the N bit data signal among an (M+N) bit data signal is applied to the other end of the thirteenth switch M13.

A driving method of the second voltage additional circuit 580 and the amplifier 540 according to a state of the third control signal φ3 and the fourth control signal φ4 is described.

In a first case, the third control signal φ3 is applied to the thirteenth switch M13, and the fourth control signal φ4 is applied to the fourteenth switch M14.

<Case 5-1> When the third control signal φ3 is in a high state and the fourth control signal φ4 is in a low state, the thirteenth switch M13 is turned on and the fourteenth switch M14 is turned off. Accordingly, the fourth voltage V4 applied to the other end of a thirteenth switch M13 is charged at the other end of the sixth capacitor C6. A voltage in which an offset voltage V_{offset} is added to the third voltage V3 is charged at one end of the sixth capacitor C6.

<Case 6-1> When the third control signal φ3 is in a low state, and the fourth control signal φ4 is in a high state, the thirteenth switch M13 is turned off and the fourteenth switch M14 is turned on. At the same time, in the second voltage additional circuit 580, the first current power source 571 is driven by the comparator 565 for performing <Case 6>. Accordingly, the same voltage amount as the fourth voltage V4 is discharged at the other end of the sixth capacitor C6 by turning on the fourteenth switch M14. Accordingly, because a total voltage of the sixth capacitor C6 decreases by the fourth voltage V4, in a process of charging again the sixth capacitor C6 by the fourth voltage V4 by the first current power source 571, a total voltage of the fifth capacitor C5 also increases by the fourth voltage V4. Therefore, the amplifier 540 outputs a seventh output voltage in which the fourth voltage V4 is added to the fifth output voltage.

In a second case, the fourth control signal φ4 is applied to the thirteenth switch M15, and the third control signal φ3 is applied to the fourteenth switch M14.

<Case 7-1> When the third control signal φ3 is in a high state and the fourth control signal φ4 is in a low state, the thirteenth switch M13 is turned off and the fourteenth switch M14 is turned on. Accordingly, a ground voltage (0V) is charged at the other end of the sixth capacitor C6. Accordingly, an offset voltage V_{offset} and the third voltage V3 (Negative Gamma voltage) is charged at one end of the sixth capacitor C6.

<Case 8-1> When the third control signal φ3 is in a high state and the fourth control signal φ4 is in a low states, the thirteenth switch M13 is turned on and the fourteenth switch M14 is turned off. At the same time, in the second voltage additional circuit 580, the second current power source 573 is driven by the comparator 565 for performing <Case 8>. The same amount of voltage as the fourth voltage V4 is charged at the other end of the sixth capacitor C6 by turning on the thirteenth switch M13. Accordingly, because a total voltage of the sixth capacitor C6 increases by the fourth voltage V4, the second current power source 573 is driven by the comparator 565. Accordingly, the sixth capacitor C6 is discharged by the fourth voltage power source V4, Accordingly, a total voltage of the fifth capacitor C5 connected with the sixth capacitor C6 in serial is decreased by the fourth voltage V4. Therefore, the amplifier 540 outputs the eighth output voltage (Negative Gamma voltage) in which the fourth voltage V4 is subtracted from the sixth output voltage (Negative Gamma voltage).

Therefore, the amplifier 540 can be further divided a level of each output voltage corresponding to 2^{M} data signals by an N bit by outputting the seventh and eighth output voltages according to driving of the second voltage additional circuit 580. Accordingly, The driving apparatus for display is effective to be increased the resolution of a driving apparatus for a flat panel display. an area of the decoder and the selection switch unit of the driving apparatus for display can be minimized, too.

Because a driving apparatus for a display in an implementation is driven with a low level of voltage, the driving apparatus for a display can be minimized a circuit area and power consumption thereof, too.

Other features will be apparent from the description and drawings, and from the claims.

What is claimed is:

1. A driving apparatus for a display comprising:
a digital/analog converter for receiving an input voltage lower than a source voltage used in a buffer amplifier for output driving, generating a plurality of reference voltages, and selecting the reference voltage corresponding to an M (M is a positive integer) bit data signal; and
an amplifier for amplifying the reference voltage selected by the digital/analog converter.

2. The driving apparatus of claim 1, wherein the digital/analog converter comprises:
a reference voltage source for generating the plurality of reference voltages using a resistor string;
a decoder for outputting the M bit data signal; and
a selection switch for selecting the reference voltage corresponding to the M bit data signal output from the decoder.

3. The driving apparatus of claim 1, wherein the amplifier comprises:
a first switch in which the reference voltage selected by the digital/analog converter is applied at one end thereof;
a second switch whose one end is connected to the other end of the first switch;
a first capacitor whose one end is connected to one end of the second switch;
a third switch whose one end is connected to the other end of the first capacitor;
a second capacitor whose one end is connected to one end of the third switch;
a fourth switch whose one end is connected to the other end of the second capacitor and whose the other end is connected to the other end of the third switch;
a fifth switch whose one end is connected to one end of the fourth switch; and
an output buffer whose inversion terminal is connected to the other end of the first capacitor and whose output terminal is connected to the other end of the fourth switch.

4. The driving apparatus of claim 3, wherein a first voltage which is a half of the source voltage is applied to the other end of the fifth switch and an non-inversion terminal of the output buffer.

5. The driving apparatus of claim 3, wherein the first control signal and the second control signal having a phase opposite to each other are intersectionally applied to the first and second switches, respectively, the first control signal is applied to the third and fifth switches, and the second control signal is applied to the fourth switch, so that the first and second capacitors are charged/discharged.

6. The driving apparatus of claim 3, wherein the amplifier amplifies the reference voltage by K (K is an integer equal to and greater than 1) times, wherein the reference voltage is selected by the digital/analog converter receiving the input voltage which is 1/k times the source voltage.

7. The driving apparatus of claim 4, wherein the amplifier amplifies the reference voltage by K/2 (K is an integer equal to and greater than 1) times, wherein the reference voltage is selected by the digital/analog converter receiving the input voltage which is 1/K times the source voltage, and subtracts the amplified reference voltage from or adds the amplified reference voltage to the first voltage.

8. The driving apparatus of claim 5, further comprising a first voltage additional circuit comprising a third capacitor whose one end is connected to one end of the second capacitor;
a sixth switch whose one end is connected to the other end of the third capacitor; and
a seventh switch whose one end is connected to the other end of the third capacitor.

9. The driving apparatus of claim 8, wherein the first control signal and the second control signal are intersectionally applied to the sixth and seventh switches, respectively, and a second voltage corresponding to the N bit data signal among a data signal of an (M+N) bit in which an N (N is a positive integer) bit is added to the M bit is applied to the other end of the sixth switch.

10. The driving apparatus of claim 1, wherein the amplifier comprises:
an eighth switch in which the reference voltage selected by the digital/analog converter is applied at one end thereof;
a ninth switch whose one end is connected to the other end of the eighth switch;
a fourth capacitor whose one end is connected to one end of the ninth switch;
a tenth switch whose one end is connected to the other end of the fourth capacitor;
a fifth capacitor whose one end is connected to one end of the tenth switch;
an eleventh switch whose one end is connected to the other end of the fifth capacitor and whose the other one is connected to the other end of the tenth switch;
a twelfth switch whose one end is connected to one end of the eleventh switch;
a comparator whose inversion terminal is connected to the other end of the fourth capacitor and for comparing magnitudes of voltages detected in an non-inversion terminal and the inversion terminal thereof and outputting a comparison signal; and
a current power source for controlling a direction of a current flowing to the fourth and fifth capacitors according to the comparison signal.

11. The driving apparatus of claim 10, wherein the current power source, according to a comparison signal of the comparator, comprises:
a first current power source for outputting a current in a direction of the fourth and fifth capacitors from the current power source; and
a second current power source for outputting a current in a direction of the current power source from the fourth and fifth capacitors.

12. The driving apparatus o—claim 10, wherein a third voltage, which is a half of the source voltage is applied to the other end of the twelfth switch and the non-inversion terminal of the comparator.

13. The driving apparatus of claim 10, wherein the third control signal and the fourth control signal having a phase opposite to each other are intersectionally applied to the eighth and ninth switches, respectively, the third control signal is applied to the tenth and twelfth switches, and the fourth control signal is applied to the eleventh switch, so that the fourth or fifth capacitors are charged/discharged.

14. The driving apparatus of claim 10, wherein the amplifier amplifies the reference voltage by k (K is an integer equal to and greater than 1) times, wherein the reference voltage is selected by the digital/analog converter receiving the input voltage which is 1/k times the source voltage.

15. The driving apparatus of claim 12, wherein the amplifier amplifies the reference voltage by k/2 (K is an integer equal to and greater than 1) times, wherein the reference voltage is selected by the digital/analog converter receiving the input voltage which is 1/K times the source voltage, and subtracts the amplified reference voltage from or adds the amplified reference voltage to the third voltage.

16. The driving apparatus of claim 13, further comprising a second voltage additional circuit comprising a sixth capacitor whose one end is connected to one end of the fifth capacitor;
a thirteenth switch whose one end is connected to the other end of the sixth capacitor; and
a fourteenth switch whose one end is connected to the other end of the sixth capacitor.

17. The driving apparatus of claim 16, wherein the third control signal and the fourth control signal are intersectionally applied to the thirteenth and fourteenth switches, respectively, and a fourth voltage corresponding to the N bit data signal among a data signal of an (M+N) bit in which an N (N is a positive integer) bit is added to the M bit is applied to the other end of the thirteenth switch.
